(19) United States
(12) Patent Application Publication
(10) Pub. No.: US 2015/0093982 A1
(43) Pub. Date: Apr. 2, 2015

(54) VENTILATED BATTERY STORAGE RACK

(71) Applicant: STEVAN M. BAILEY, LAGUNA BEACH, CA (US)

(72) Inventor: STEVAN M. BAILEY, LAGUNA BEACH, CA (US)

(21) Appl. No.: 14/500,999

(22) Filed: Sep. 29, 2014

Related U.S. Application Data
(60) Provisional application No. 61/885,856, filed on Oct. 2, 2013.

(51) Int. Cl. H05K 7/20

(52) U.S. Cl. CPC H05K 7/20145
USPC 454/184

(57) ABSTRACT

The invention includes a ventilated storage rack unit and complete storage rack system for storing an array of battery cells in an uninterrupted power source that meets the seismic testing requirements of NEBS GR-63-CORE (Issue 2 Apr. 2002). The storage rack unit of the present invention incorporates a vented vertical plenum for evacuating heated air generated by the contents of the storage rack system by providing a vertical passage to passively or actively evacuate the heated air. The present invention further incorporates locking dimples on the perimeter frame assembly and the vertical plenum positioned between horizontal base panels in the internal compartment of the storage rack unit and spaced as needed between battery cells to secure kind lock the storage rack unit contents in place during a shaking event.

### CROSS REFERENCE TO RELATED APPLICATIONS

This application claims the benefit of U.S. Provisional Application No. 61/885,856 filed Oct. 2, 2013, the disclosure of which is incorporated herein by reference.

### FIELD OF THE INVENTION

The present invention relates to battery storage racks, and more particularly relates to a ventilated battery storage rack unit particularly suited for securely storing an array of battery cells for an uninterruptible power source.

### BACKGROUND

There are many configurations and applications of general storage racks known in the industry including for warehouse storage, retail storage, lumber storage and limitless other applications. Many storage racks are designed for transient storage of items, while others are designed for longer term or semi-permanent storage. Storage racks generally have few requirements beyond structural integrity unless required for specialty applications. One such specialty application is in the telecommunications or related industry where there is need for the semi-permanent storage of backup power supplies consisting of racks of low voltage batteries.

The batteries for these backup power supplies can be large, contain caustic materials and are relatively heavy. While stored they are electrically connected to the power grid as well as a power source for charging and produce a significant amount of heat as they continuously undergo the cycle of discharging and charging such that they are always nearly fully charged and available for use. As a result of the generation of heat, adequate ventilation through any storage rack is needed to avoid overheating of the batteries which may lead to a reduced effective life. Additionally, a result of the natural heating of the batteries through charge and discharge, the batteries tend to swell and so space and gaps between adjacent batteries must be provided to accommodate such swelling or bulging. At the same time, appropriate means of aligning and securing fresh batteries that have not begun to bulge is needed that will not damage or interfere with the batteries or their function once they do begin to swell.

Exacerbating the problem of heat generation in existing storage racks is that multiple storage racks are generally stacked onto each other and multiple storage racks are generally located immediately next to each other such that there is little space between each storage rack. This allows little to no cross ventilation to remove heat generated by the contents such as the intended battery arrays.

The industry-wide practice is to use cell spacers consisting of cut sheets of one-half inch thick rigid plastic foam as gap spacers between battery cells. If the battery casings maintain the same size and shape, such a solution is satisfactory, although it does riot permit ventilation between the cells. Further, such practice does not provide a complete blockage to battery movement or shifting during a seismic activity. Some practice is also made of pins or rods to separate batteries, but this may interfere with the natural battery bulging and could create damage. The bulging usually begins at a low level, increases to a maximum at the middle of the cell casing and then recedes to essentially normal dimensions at the top of the cell easing and the cover. Thereafter the battery casings are forced apart by the continuing bulging. Since connections between posts of opposite polarity in adjacent cells are frequently made of heavy conductive metal, typically copper connectors, which are rigidly connected to the respective posts, movement of the cases relative to one another, resulting from bulging, sometimes results in bending of terminal posts and/or breaking of the seals between the battery case and the terminal.

As the battery arrays are electrically connected they must not move such that they could shift or fall and dislodge, the electrical connections or release the caustic materials inside. Such potential movement would likely come at the time of an emergency when the main power grid is compromised and the backup batteries are most needed.

While the batteries for these backup power supplies can be large, contain caustic materials and are relatively heavy, individually, they are most often stored on storage racks that hold several batteries up to several feet high. This requires a very heavy and well-constructed storage rack. Such a heavy storage rack may be too heavy and large to put in place in an office building or other light industry location. As such, there is a need for a rack that can be quickly and easily assembled on site. Current storage racks are either single units or require great effort to bolt and couple the smaller units together to form the complete storage rack.

Furthermore, these heavy storage racks may be unstable if not securely mounted and secured to its surroundings to limit the likelihood of collapse and potentially release of the caustic battery materials in an unstable environment such as during earth movement or an earthquake. Current methods of attachment to flooring require disassembly of the rack to access base components, bolting to the floor or other attachment location and cumbersome reassembly of the rack,

The telecommunications industry and other industries use backup power supplies or “uninterruptible power sources” (UPS's) to maintain operations when primary power sources fail or are interrupted. These UPS's are used to supply backup power to critical electrical and electronic equipment during primary power interruptions. Often these backup power sources include arrays of 2-volt valve-regulated lead acid battery cells (VRLA's). For example, a 48-volt backup power supply may include an array of twenty-four 2-volt VRLA's interconnected in series to supply backup power to critical equipment. Alternatively, a 24-volt backup power supply may include an array of twelve 2-volt VRLA's. These battery cells typically are supported on racks in a desired array. An example of a metal UPS rack is described in U.S. Pat. No. 6,719,150, Such racks may support battery cells in a 3 by 8 array (48-volt array), or in a 3 by 4 array (24-volt array), for example, depending upon the desired or required amount of backup power. A variety of other battery array arrangements are possible and often utilized such as 2 by 6 array, 4 by 6 array. 6 by 4 array, etc.

The telecommunications industry has widely adopted a set of industry standards known as the NEBS (“Network Equipment—Building System”) standards. The NEBS standards were developed by Bell Labs in the 1970's to standardize equipment that would eventually be installed in either an Incumbent Local Exchange Carrier (ILEC) or Regional Bell Operating Company (RBOC) Central Office. the NEBS standards basically describe the environment of a typical or generic RBOC Central Office. Bell Labs' intent in developing the NEBS standards was to make it easier for vendors to design and supply equipment compatible with a generic RBOC Central Office environment.

The main NEBS standard is Bellcore (now Telcordia) GR-63-CORE “Network Equipment—Building System (NEBS) Requirements: Physical Protection,” Section 4.4, entitled “Earthquake, Office Vibration, and Transportation Vibration,” provides generic criteria for earthquake, office vibration, and transportation vibration for telecommunications network equipment. Section 4.4.1 entitled “Earthquake Environment and Criteria” defines the seismic shaking conditions that must be withstood by a particular piece of equipment to be NEBS certified. Thins section requires the equipment to withstand a most severe “Zone 4 seismic event,” which is approximately equivalent to an earthquake having a rating, of 8.2 on the Richter scale. GR-63-CORE section 5.4.1 defines the waveform testing requirements necessary to demonstrate NEBS GR-63-CORE seismic compliance.

Current approaches for protecting telecommunications racks and enclosures from seismic movement are often costly, however, and not well suited for efficient use with standard sized telecommunications battery cells and components and often fail to provide means of stabilizing the battery cells within the enclosure. For example, in some cases custom storage racks in rooms are built to store telecommunications battery arrays. In other cases, vendors lease multiple telecommunications rooms or spaces in which to store vast arrays of battery cells to maintain adequate redundancy for such emergency situations.

While some battery storage racks and systems may be available that claim to pass the NEBS GR-63-CORE (Issue 2 Apr. 2002) seismic testing requirements, many provide no restraint on the batteries shifting or moving within a shelf. While the storage rack structure itself may resist damage, the shifting batteries may damage not only the batteries themselves, but also may stretch, break or deform the connecting cables, disrupting the effective delivery of power from the batteries to the telecommunications network. Prior shelving systems may include gaps or spacing, perhaps with bumps or pins between the adjacent battery cells to allow for cooling ventilation, these are not designed nor function to stabilize and resist movement or shifting of the batteries during a shaking such as for testing or an earthquake.

What is needed are improved, battery storage rack protection systems and methods that provide secure stabilization of standard telecommunications backup power sources, while utilizing minimal floor space or meeting other spatial dimension requirements for a telecommunications room or space. Embodiments of the present invention address such needs.

Accordingly, there is a need for storage racks capable of holding backup batteries that comply with the NEBS GR-63-CORE (Issue 2 Apr. 2002) seismic testing requirements. Preferably such a system is adaptable to any standard size and array of low volt battery cells. Such a storage rack should be efficient to construct, should occupy a minimum amount of space, should be relatively light, and should be relatively affordable compared to non-NEBS certified storage systems.

### SUMMARY

Embodiments of the present invention relate to storage rack units and complete storage rack systems for backup power supplies, and in particular storage rack systems and methods for protecting backup batteries and equipment that use stackable storage rack units that are adapted to allow for effective ventilation to remove damaging heat from within the storage rack unit generated by the continuous cycling of the batteries.

Further embodiments provide for easy access assembly of the storage rack units into a complete storage rack system tor containing the backup batteries as well as mounting brackets for efficient mounting to the floor or other attachment point that does not require disassembly of the storage rack.

A further embodiment provides means for securely containing the batteries within the storage rack unit for protecting the backup batteries from shaking damage including that caused by an earthquake or other seismic movement.

The present invention includes a storage rack for receiving and securely supporting a plurality of battery cells in. a spaced array. The storage rack is configured to meet the seismic testing requirements of NEBS GR-63-CORE, Section 4.1.1 (Issue 2, April 2002).

The present invention is further directed to providing spacing between casings of adjacent battery cells on a storage rack shelf so that the battery cells are not materially affected by bulging which often occurs in the normal course of battery cell life. At the same time, the present invention facilitates ventilation between the battery casings of adjacent cells, which is not possible using, prior art rigid foam sheet spacers. Good ventilation benefits battery performance and life.

The battery storage rack includes a perimeter frame assembly having a top edge and a bottom edge an engineered horizontal base having a top face and a bottom face, the top face attached to the bottom edge of the perimeter frame assembly; a vented vertical plenum having a top edge and a bottom edge, wherein the bottom edge is attached to the top face of the engineered horizontal base, wherein the engineered horizontal base is at least partially absent beneath the vented vertical plenum in an area defined by the internal perimeter of the vented vertical plenum bottom edge to allow for full vertical evacuation of accumulated hot air within the storage rack unit.

To allow for secure positioning and stabilization of the battery arrays within the storage rack, the plenum of the ventilated storage rack unit may optionally including locking dimples on its exterior to contact and secure each battery stored within the storage rack unit. To further secure the batteries within the ventilated storage rack unit the interior face of the perimeter frame assembly opposing and similar locking dimples.

Each ventilated storage rack unit has a plurality of internal positioning pins at the rear of the engineered horizontal base or the rear of the bottom edge of the perimeter frame assembly. These positioning pins allow for quick and efficient assembly of the separate storage rack units into a complete storage rack system by contacting and interlocking with the top edge of the perimeter frame assembly. This allows an assembler to quickly slide a top unit on top of and interlock with the bottom unit to stack and assemble a complete storage rack system.

To complement assembly of a complete storage rack system, each ventilated storage rack unit has an internal assembly aperture or plurality of internal assembly apertures for easy access to internal assembly bolts. These internal assembly apertures for assembly bolts are generally located only at the front of the unit since the rear positioning pins securely engage the rear of each storage rack unit. The assembly bolts are located internal of each storage rack unit accessible through the internal assembly apertures so that the units may be spaced directly adjacent each other reducing wasted space between adjacent complete storage rack systems without protruding, bolt assemblies.

A further embodiment of the storage rack unit is the inclusion of internal floor mounting brackets wherein the internal floor mounting brackets are accessible through the internal assembly aperture holes in the unit without disassembly.

These and other aspects of the invention will be better understood from a reading of the following detailed description together with the drawings.

### BRIEF DESCRIPTION OF THE DRAWINGS

FIG. 1 schematically illustrates a ventilated storage rack unit having a vented vertical plenum and tacking dimples.

FIG. 2 illustrates multiple ventilated storage rack units stacked upon each other to create a complete storage rack system assembled through internal assembly aperture with internal assembly bolts and internal mounting brackets.

FIG. 3 shows a top down view of the storage rack unit illustrating the optional openings in the horizontal base shelf for the vertical plenum and an optional placement of the positioning pins.

FIG. 4 shows an end view of a storage rack unit illustrating an alternate placement of the positioning pins at the rear of the underneath side of the horizontal base panel.

### DETAILED DESCRIPTION

The present invention is a ventilated storage rack unit having a central ventilation plenum for evacuating heat generated by contents stored within the unit. Embodiments of the present invention hardier incorporate locking dimples for securing contents of the storage rack unit and to resist movement of the contents during an earth movement or other shaking of the unit when in use. Additional embodiments of the present invention are designed for easy assembly of the storage rack units into complete storage rack systems by incorporating positioning pins and easy access internal assembly bolts. Further embodiments include internal mounting brackets to facilitate efficient mounting of it storage rack unit or fully assembled complete storage rack system to the floor or other permanent surface to which the storage rack system is to be attached.

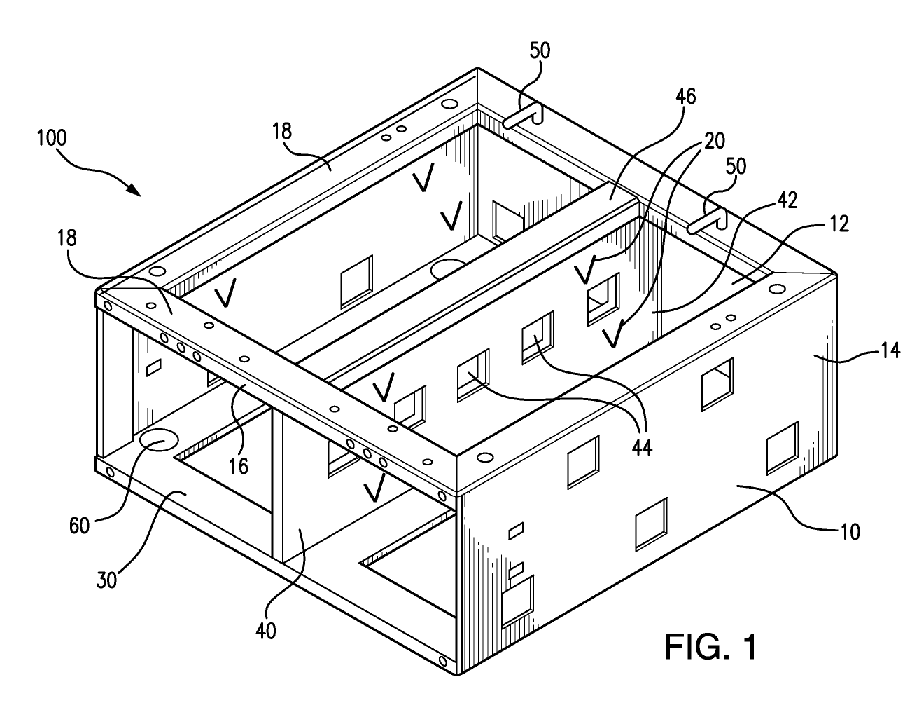

FIG. 1 illustrates an embodiment of ventilated storage rack unit 100 according to the present invention with vertical plenum 40 constructed of two adjacent and parallel vertical plenum side members 42 forming a vented plenum, with ventilation holes 44 and locking dimples 20 in the side members, and reinforcement flanges 46 on the top and the bottom edge. Horizontal base panel 30 and perimeter frame assembly 10 with rear panel 12, vertical side panel 14, upper horizontal member 16, and a reinforcement flange 18. Positioning pin 50 is on the top edge of vertical rear panel 12 of the perimeter frame assembly 10. Positioning pin 50 may also be on the back or the underside of horizontal base panel 30 or on the top of reinforcement flange 18. Also shown is assembly aperture 60.

Vertical plenum 40 within ventilated storage rack unit 100 provides a means of exhausting, hot air generated by the contents of the storage rack unit. Vertical plenum 40 is preferably a structural element attached to divide perimeter frame assembly 10 of the storage rack unit 100 into a plurality of compartments designed to accommodate batteries intended to be stored within storage rack unit 100.

Vertical plenum 40 allows for active or passive vertical evacuation of air from ventilated storage rack unit 100. Evacuation of heated air through vertical plenum 40 is optimally by passive means allowing natural convective currents of warm air to rise up and through vertical plenum 40 and pulling heated air from within storage rack unit 100 into vertical the plenum 40 and out the top of the storage rack unit 100 or complete storage rack system 200. Alternatively, some means of active removal of the heated air from the plenum may be added such as a fan to push or pull the heated air from the plenum.

Vertical plenum 40 shall have side members 42 defining a plurality of ventilation holes 44 to allow higher temperature air within the compartments of storage rack unit 100 to pass into vertical plenum 40 for evacuation. Such heat within the compartments is likely to be generated by the charge and discharge cycling of the batteries stored within storage rack unit 100.

Vertical plenum 40 is structurally engineered to support storage rack unit 100 to hold the contents of storage rack unit 100, such as batteries. Vertical plenum 40 divides the interior of storage rack unit 100 into adjacent and similarly sized interior compartments within perimeter frame assembly 10. Vertical plenum 40 is optimally constructed of the same or similar material as perimeter frame assembly 10, generally steel or high strength aluminum.

Vertical plenum 40 may be constructed of two parallel vertical plenum side members 42 forming a plenum within attached by welding or other permanent means of attachment to rear panel 12 of perimeter frame assembly 10 and to upper horizontal member 16 and to horizontal base panel 30. Alternate means of creating vertical plenum 40 may be multiple tubes with holes in their sides that are attached to perimeter frame assembly 10 allowing for evacuation of the hot air or other similar means of creating such a hollow chimney space for vertical evacuation of heated air. Further means of creating vertical plenum 40 may be a single wall that is corrugated around the vent holes in horizontal base panel 30.

Vertical plenum 40 may further incorporate optional reinforcement flange 46 to the top and the bottom edge of vertical plenum 40 for additional structural integrity. When such pieces are added they must have ventilation holes to allow for vertical flow of heated air through vertical plenum 40. Such holes in top reinforcement flange 46 must further be designed to align with holes in any bottom reinforcement, flange 46, and horizontal base panel 30, to allow for vertical flow of heated air through vertical plenum 40 between a stack of multiple storage rack unit 100 when forming storage rack system 200.

FIG. 1 further illustrates locking dimples 20 as protrusions from the surface of parallel vertical plenum side members 42 of vertical plenum 40 directed toward the interior compartment of storage rack unit 100 and toward the intended contents within.

Locking dimples 20 are located on vertical plenum 40 to provide stability and to secure the contents within an interior compartment of storage rack unit 100. Locking dimples 20 protrude from the side members 42 of vertical plenum 40 into the interior compartment of storage rack unit 10 and may be similar to locking dimples 20 protruding into the interior compartment of storage rack unit 100 from the vertical engineered side panel 14 of the perimeter frame assembly 10. The locking dimples on vertical plenum 40 and vertical engineered side panel 14 may be different depending upon the intended contents and configuration within storage rack unit 100.

Locking dimples 20 may be rubber tabs attached securely enough to parallel vertical plenum side members 42 that it is permanently affixed and will not release during earth movement Alternatively, locking dimple 20 may be a metal tab welded or bolted or stamp cut out of parallel vertical plenum side members 42 and bent to extend into the interior compartment of storage rack unit 100. Most optimally, the locking dimple 20 shall be created by a protrusion of the surface of the vertical plenum by extending a local area of the side of the plenum.

Locking dimples 20 must not be sharp, abrasive or otherwise be capable of piercing or damaging a battery or other contents stored within storage rack unit 100.

Locking dimples 20 should be structurally sound such that they do not bend under the weight of moving and shifting battery arrays so as to continue to secure and stabilize the battery arrays, especially as during an earthquake. Locking dimples 20 may be integrated, into vertical plenum 40 or perimeter frame assembly 10 by stamping the metal used for the members to create locking dimple 20 incorporated into the metal itself or locking tab 20 may be preformed and then bolted or welded onto vertical, plenum 40 or perimeter frame assembly 10, although this may incorporate additional cost into the finished storage rack unit,

An individual locking dimple 20 may extend as little as about 0.25 inch from parallel vertical plenum side members 42 or from perimeter frame assembly 10 toward the interior compartment, so as to extend to just contact the face of the battery intended to be located on that shelf Locking dimple 20 may extend further depending upon the battery size, type and configuration located within storage rack unit 100 so long as locking dimple 20 extends to just contact the face of the battery on that shelf. However, it is preferred that the length the locking dimple 20 not provide a protrusion that may interfere with the battery casing when the battery swells or bulges during storage and use. Locking dimple 20 may be located at any preferred height and location on parallel vertical plenum side members 42 or perimeter frame assembly 10 within storage rack unit 100 and above horizontal base panel 30 such that it may most effectively resist the shifting of the battery and keep batteries secure.

Locking dimples 20 may be any one of several shapes from a simple conical or semi-spherical dimple in the metal to a rod or pin, to a more complex triangular, conical or trapezoidal shape so as to more easily receive and lock a battery or other intended content into place. The width of locking dimple 20 may be not less than about 0.5 inches so as to allow adequate air flow between the batteries for cooling and not provide a sharp protrusion that may damage a battery. The width may be as wide as desired in order to provide greater ventilation of heated air into vertical plenum 40 or for other purposes to provide the desired spacing between batteries. Sharp points or edges should be avoided to limit any potential damage to a battery as it is received by storage rack unit 100 or during use when the battery array or other intended content may shift.

Locking dimples 20 will resist movement of the battery within the interior compartment of storage rack unit 100 during a shaking of the storage rack system 200 such as from an earthquake. As the battery array is electrically interconnected with heavy gage cables or plates, there is little tolerance for such movement without the risk of disconnections, breakage or shorting of the cables and connections.

FIG. 1 further illustrates perimeter frame assembly 10 consisting of vertical engineered rear panel 12 and vertical engineered side panel 14. Vertical engineered rear panel 12 has a first vertical edge and a second vertical edge and a horizontal bottom edge and horizontal top edge. Vertical engineered side panel 14 has a rear vertical edge, a front vertical edge and a horizontal bottom edge and horizontal top edge. Vertical engineered rear panel 12 is attached along the first vertical edge to the rear vertical edge of a first vertical engineered side panel 14 and along the second vertical edge to the rear vertical edge of a second vertical engineered side panel 14 to create perimeter frame assembly 10. The rear vertical edge of the first vertical engineered side panel 14 is fixably attached to the first vertical edge of the vertical engineered rear panel 12 and the rear vertical edge of the second vertical engineered side panel 14 is fixably attached to the second vertical edge of the vertical engineered rear panel 12.

Perimeter frame assembly 10 forms an interior compartment of storage rack unit 100 designed to accept and secure batteries in place. Securing the batteries is achieved by incorporating locking dimples 20 provided on the parallel vertical plenum side members 42 of vertical plenum 40. Additionally, locking dimples 20 are preferably provided on vertical engineered, side panel 14, protruding toward the interior compartment, extending from the surface of vertical engineered side panel 14 just far enough that locking dimples 20 engage and come into contact with a battery or other contents positioned within the interior compartment of storage rack unit 10.

Perimeter frame assembly 10 is preferably constructed of steel or high strength aluminum although other high strength construction materials such as carbon fiber or fiberglass composites could be used. The material used shall be designed and engineered with such structural integrity to hold the intended contents of storage rack unit 100 including such heavy batteries.

Upper horizontal member 16 is attached across the front of perimeter frame assembly 10 as shown in FIG. 1 and stabilizes and completes perimeter assembly 10. Upper horizontal member 16 has a first end and a second end, wherein the first end is fixably attached near and preferably to the front vertical edge of the first vertical engineered side panel 14 and the second end is fixably attached near and preferably to the front vertical edge of the second vertical engineered side panel 14.

Optional reinforcement flange 18 may be added to the top edge of vertical engineered rear panel 12 and vertical engineered side panel 14 of perimeter frame assembly 10 and upper horizontal member 16 for additional structural integrity. Reinforcement flange 1$ may be pieces that are welded to perimeter frame assembly 10 or may be extensions of vertical engineered rear panel 12 and vertical engineered side panel 14 continuously rolled over to form a flange along the top edge of perimeter frame assembly 10 providing additional strength and rigidity to storage rack unit 100.

FIG. 1 further illustrates engineered horizontal base panel 30. Horizontal base panel 30 has a top face and a bottom face, wherein the top face is fixably attached to the bottom edge of perimeter assembly 10, specifically the bottom edge of the vertical engineered side panel 14 members, and the bottom edge of the vertical engineered rear panel 12 and to the bottom edge of vertical plenum 40.

Engineered horizontal base panel 30 acts as a shelf and is structurally engineered to hold the contents of the storage rack unit 100 such as heavy batteries. Engineered horizontal base panel 30 must be structurally designed to carry the heavy loads intended to be placed in the interior compartments of storage rack unit 100 and may be a single sheet of steel or other sturdy metal or may be two or more layers of such material as needed to support the intended weight of the storage rack unit and contents. Horizontal base panel 30 members are of a compatible material to perimeter frame assembly 10 and vertical plenum 40 members, preferably steel to allow for secure welding of horizontal base panel 30 to the other members. Horizontal base panel 30 members should be engineered and designed to accommodate the weight and dimensions of the particular type of batteries, equipment or other material to be stored within storage rack unit 100.

Horizontal base panel 30 may be configured as ribbed, flat, or other accommodating shape designed to receive and support the batteries, Horizontal base panel 30 to may be flat or laterally ribbed to provide additional strength to the shelf member tract provides an opportunity to utilize thinner gauge steel and to reduce the overall weight of storage rack unit 100.

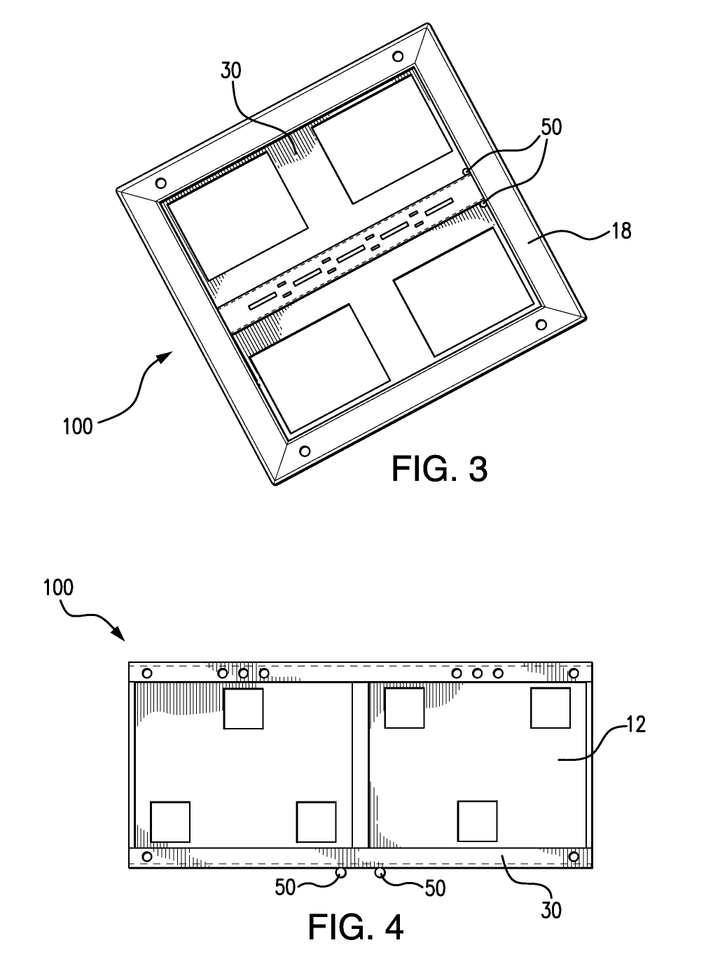

FIG. 3 is a top down view of engineered horizontal base panel 30 illustrating drat engineered horizontal base panel 30 includes optional one or more preferred openings or cut-outs. Importantly, as shown in FIG. 3, the preferred openings in engineered horizontal base pan 30 are present at least partially beneath the location of vented vertical plenum 40. Engineered horizontal base panel 30 must be at least partially absent beneath vertical plenum 40 in an area defined by the internal perimeter of the bottom edge of ventilated vertical plenum 40 to allow for full vertical evacuation of accumulated hot an within storage rack unit 100. These areas absent in horizontal base panel 30 may comprise a plurality of various sized and shaped holes or may be completely absent depending upon the full design of storage rack unit 100.

Horizontal base panel 30 preferably has one or more holes or cut-outs, within design allowances, to allow higher temperature air within the interior compartments of storage rack unit 100 to flow to and through vertical plenum 40 or to otherwise aide in the evacuation of heated air by allowing it into vertical plenum 40, and to reduce the weight of storage rack unit 100 especially in a complete storage rack system 200.

FIG. 4 is an end view of storage rack 100 that further illustrates the alternate placement of positioning pins 50 on the back and on the underside of engineered horizontal base panel 30. This placement of positioning pins 50 allows the pins to easily engage beneath a rolled reinforcement flange 18 on the perimeter assembly to secure two storage units in place,

Positioning pin 50 is added to the top edge of vertical engineered rear panel 12 of the perimeter frame assembly 10 of a first storage rack unit 100 designed to accept and engage at least some portion of engineered horizontal base panel 30 on a second storage rack unit 100 that may be stacked upon the first storage rack unit 100. To assure proper and more exacting alignment when stacking storage rack unit, multiple positioning pins may be utilized. Positioning pm 50 may be a pin or tab or flange or other protrusion that is welded or permanently formed and affixed to vertical engineered rear panel 12.

To accept positioning pin 50, a receiving flange, hole or other receptacle is needed on at least some portion of engineered horizontal base panel 30 of the second storage rack unit 100. This may be merely a hole or series of holes to accept the position pins on the lower storage rack unit in a storage rack system or it may be tubes welded to the base panel or to receiving flange or other means of providing at least a nominal level of interlocking mechanism between two stacked storage rack units.

FIG. 3 further illustrates an alternate location of positioning pins 50 is shown attached to reinforcement flange 18 on perimeter assembly 10.

In the alternative, as per the design of the storage rack unit, positioning pin 50 may be placed on the lower edge of vertical engineered rear panel 12 or along some portion of engineered horizontal base panel 30 with its corresponding receptacle placed on the to edge of vertical engineered rear panel 12 of the perimeter frame assembly 10.

Preferably, positioning pin 50 is preferably about 0.5 in long and welded to the bottom face of engineered horizontal base panel 30, or on the horizontal bottom edge of vertical engineered rear panel 12 near a vertical edge. Positioning pin 50 may be from about 0.2 to about 2.0 inches long depending upon the battery size, shape and configuration within the storage rack. In this location, there is no need for a separate receiving flange, hole or other receptacle because the positioning pin may engage below the wiled top flange created by the engineered rear panel 12.

Positioning pins and corresponding receptacles may also be placed on the rear edge of as vertical plenum 40 or the rear vertical edge of vertical engineered side panel 14.

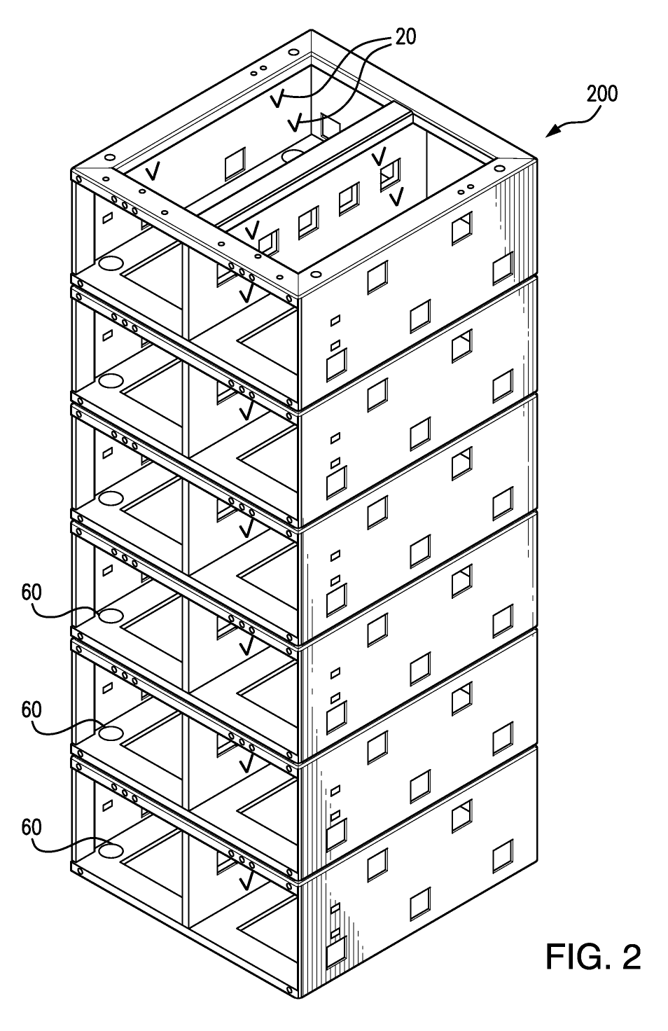

FIG. 1 illustrates internal assembly aperture 60 provided within engineered horizontal base panel 30. As shown in FIG. 1, engineered horizontal base panel 30 consists is of preferred double wall construction to provide the necessary strength to carry the significant loads intended for a complete storage rack system 200 as shown in FIG. 2.

Internal assembly aperture 60 is preferably located within the double wall construction of horizontal base panel 30 with an access opening provided within the upper wall of horizontal base panel 30 to the cavity between the double walls of the horizontal base panel 30 and the hole within the lower wall of base panel 30 through which an assembly bolt or mounting bracket bolt may extend. Within the walls of base and 30 and extending through the lower wall of base panel 30 is the assembly bolt or mounting bracket bolt.

Upper horizontal member 16 of a second storage rack unit 100 may connect into or the upper edge of the perimeter frame assembly 10 below using an assembly bolt to assemble complete storage rack system 200.

A mounting bracket bolt may extend through internal assembly aperture 60 to connect storage rack unit 100 to the floor or other fixed surface to which a complete storage rack system 200 is to be mounted. The internal bolts may be of any various standard nut and bolt systems adequate to either assemble the storage rack units into a storage rack system or to securely mount a storage rack system to a fixed surface.

FIG. 2 illustrates multiple storage rack unit 100 members stacked upon each other and assembled to form storage rack system 200 assembled through internal assembly aperture 60. Locking dimples 20 in the side members 42 are shown in each separate storage rack unit 100 to provide optimal separation and locking of individual battery cells intended to be secured within.

FIG. 2 complete storage rack system 200 is created when multiple storage rack unit. 100 members are stacked one upon the other, Multiple storage rack unit 100 members can be stacked as high as the engineering design of the complete storage rack system allows when fully loaded. Each storage rack unit 100 is generally stacked upon the other and then multiple complete storage rack system 200 are generally located immediately next to each other such that there is little space between each storage rack system 200. While this arrangement allows little to no cross ventilation between racks to remove heat generated by the contents such as the intended battery arrays, the vertical plenum design of the present invention allows the generated heat to be effectively removed from each complete storage rack system 200, regardless of how close they are installed to each other.

FIG. 2 complete storage rack system 200 is designed and constructed to meet or surpass the seismic testing, requirements of NEBS GR-63-CORE, Section 4.1.1 (issue 2, April 2002). More specifically, the complete storage rack system is designed and constructed to sustain the waveform testing defined by NEBS GR-63-CORE without permanent structural or mechanical damage. Storage rack system 200 of this invention is designed to meet or surpass the seismic testing requirements of any particular one in which the system is installed.

The above detailed description of exemplary embodiments of the invention is provided to illustrate the various aspects of the invention, and is not intended to limit the scope of the invention thereto. Persons of ordinary skill in the art will recognize that certain modifications can be made to the described embodiments without departing from the invention. For example, while the above-described embodiments of the invention have been principally described in connection with the storage of battery cells for backup power systems, a storage system according to the invention may also be configured and used to support other objects or equipment. All such modifications are intended to be within the scope of the appended claims.

What is claimed is:

1. A ventilated storage rack unit for storing an array of battery units in an uninterrupted power source, the ventilated, storage rack unit comprising:
a. a perimeter frame assembly having a top edge and a bottom edge forming an internal compartment;
b. an engineered horizontal base having a top face and a bottom face, the top face attached to the bottom edge of the perimeter frame assembly;
c. a vented vertical plenum having a top edge and a bottom edge defining an internal perimeter, wherein the bottom edge is attached to the top face of the engineered horizontal base;
d. wherein the engineered horizontal base is at least partially absent beneath the vented vertical plenum in an area defined by the internal perimeter of the vented vertical plenum bottom edge.

2. The ventilated storage rack unit as claimed in claim 1 wherein the vented vertical plenum divides the internal compartment of the storage rack unit into a plurality of battery compartments,

3. The ventilated storage rack unit as claimed in claim 1 wherein the vented vertical plenum is adapted far active or passive vertical evacuation of higher temperate air from the storage rack unit.

4. The ventilated storage rack unit as claimed in claim 1 wherein the vented vertical plenum comprises parallel vertical sides with a plurality of ventilation holes adapted to allow higher temperature air within the internal compartment to pass nub the vented vertical plenum for evacuation.

5. The ventilated storage rack unit as claimed in claim 1 wherein the vented vertical plenum comprises two parallel vertical sides having a plurality of locking dimples extending from a surface of a vertical side into the internal compartment.

6. The ventilated storage rack unit as claimed in claim 1 wherein the perimeter frame assembly comprises a plurality of locking dimples extending from a surface of the perimeter frame assembly into the internal compartment.

7. A ventilated storage rack unit for storing an array of battery units in an uninterrupted power source, the storage rack comprising:
a. a perimeter frame assembly forming an internal compartment comprising:
i. a vertical engineered rear panel having a first vertical edge, a second vertical edge and a horizontal bottom edge;
ii. a first vertical engineered side panel having a rear vertical edge, a front vertical edge and a horizontal bottom edge, and a second vertical engineered side panel having a rear vertical edge, a front vertical edge and a horizontal bottom edge;
iii. wherein the rear vertical edge of the first vertical engineered side panel is fixably attached to the first vertical edge of the vertical engineered rear panel and the rear vertical edge of the second vertical engineered side panel is fixably attached to the second vertical edge of the vertical engineered rear panel;
iv. an upper horizontal member having a first end and a second end, wherein the first end is fixably attached to the front vertical edge of the first vertical engineered side panel and the second end is fixably attached to the front vertical edge of the second vertical engineered side panel;
b. an engineered horizontal base panel having a top face and a bottom face, wherein the top face is fixably attached to the bottom edge of the first vertical engineered side panel, the bottom edge of the second vertical engineered side panel, and the bottom edge of the vertical engineered rear panel; and
c. a vented vertical plenum.

8. The ventilated storage rack unit as claimed in claim 7 wherein the vented vertical plenum divides the internal compartment oldie storage rack unit into a plurality of battery compartments.

9. The ventilated storage rack unit as claimed in claim 7 wherein the vented vertical plenum comprises two parallel opposing vertical sides.

10. The ventilated storage rack unit as claimed in claim 7 wherein the vented vertical plenum comprises a single corrugated vertical side panel.

11. , The ventilated storage rack unit as claimed in claim 7 wherein the vertical engineered side panels comprises a single construction material.

12. A plurality of storage rack units as claimed in claim 7 stacked vertically upon each other forming a completed storage rack system.

13. . The ventilated storage rack unit as claimed in claim 7 comprising a plurality of internal assembly aperture adapted to accept internal assembly bolts wherein the assembly bolts are accessible through the internal assembly aperture.

14. The ventilated storage unit as claimed in claim 7 comprising a plurality of internal assembly aperture adapted to accept internal floor mounting brackets wherein the internal floor mounting brackets are accessible through the internal assembly aperture without disassembly of the storage rack unit.

15. The ventilated storage rack unit as claimed in claim 7 having a plurality of positioning pins.

16. The ventilated storage rack unit of claim 7 wherein the storage rack unit at least meets the seismic testing requirements of NEBS GR-63-CORE (Issue 2, April 2002).
